(19) United States
(12) Patent Application Publication
(10) Pub. No.: US 2019/0112700 A1
(43) Pub. Date: Apr. 18, 2019

(54) METHOD FOR PARTICLE SURFACE TREATMENT OF A CERAMIC POWDER AND CERAMIC POWDER PARTICLES OBTAINED BY SAID METHOD

(71) Applicant: The Swatch Group Research and Development Ltd., Marin (CH)

(72) Inventors: Csilla MIKO, Essertines-sur-Yverdon (CH); Jean-Luc BAZIN, Tuescherz-Alfermee (CH)

(73) Assignee: The Swatch Group Research and Development Ltd, Marin (CH)

(21) Appl. No.: 16/112,821

(22) Filed: Aug. 27, 2018

(30) Foreign Application Priority Data
Oct. 12, 2017 (EP) 17196219.4

(51) Int. Cl. C23C 14/22; C23C 14/48; C23C 14/06; C04B 35/56; C04B 35/565; C04B 35/584; C04B 35/48; C04B 35/10; C04B 35/628

(52) U.S. Cl. CPC C23C 14/223; C04B 2235/3895; C23C 14/0664; C23C 14/0676; C23C 14/067; C04B 35/5611; C04B 35/565; C04B 35/584; C04B 35/48; C04B 35/10; C04B 35/628; C04B 35/62836; C04B 35/62828; C04B 2235/3843; C04B 2235/3826; C04B 2235/3873; C04B 2235/3244; C04B 2235/3217; C04B 2235/3856; C23C 14/48

(57) ABSTRACT

The invention concerns a method for surface treatment of a ceramic material in powder form, wherein said method comprising the step of providing a powder formed of a plurality of particles of the ceramic material to be treated, and wherein said ceramic powder particles are subjected to an ion implantation process by directing towards an external surface of said particles a beam of singly or multiply charged ions produced by a charge of singly or multiply charged ions, for example of the electron cyclotron resonance ECR type, wherein said particles have a generally polyhedral shape.

The invention also concerns a material in powder form, formed of a plurality of particles having a ceramic external layer and a ceramic core, wherein said particles have a generally polyhedral shape.

This application claims priority from European Patent Application No. 17196219.4 filed on Oct. 12, 2017, the entire disclosure of which is hereby incorporated herein by reference.

### FIELD OF THE INVENTION

The present invention concerns a method for the particle surface treatment of a ceramic material in powder form and ceramic powder particles obtained by implementation of such a method. The ceramic powder particles obtained by the method according to the invention are intended for the manufacture of shaped products, i.e. parts delivered in their final form and realized by means of sintering methods such as sintering at atmospheric pressure, or hot isostatic pressing, known as HIP.

### BACKGROUND OF THE INVENTION

The mechanical and physical properties of materials are closely linked to the electronic structure of the atoms that compose them and to the way in which they are bonded to each other. Materials can therefore be classified in three main categories depending upon the type of bond between the atoms which compose them: metals (metallic bonds), ceramics (covalent or ionic bond) and polymers (hydrogen bond). Since covalent and ionic bonds are stronger energetically than metallic bonds, ceramics are harder, have a higher melting point and higher chemical stability than metals. Moreover, the absence of free electrons means that ceramics have very low electrical and thermal conductivity. For the same reasons, there is some conflict between the hardness of a material (which depends on the strength of the bond between the atoms and their ability not to move under stress), and its resistance to shocks (which depends on the ability of the material to dissipate energy through the movement of atoms).

Ceramic materials can be defined as inorganic, non-metallic materials requiring high temperatures during manufacture. The firing or sintering of ceramic materials is carried out, however, at temperatures well below their melting point. If ceramics are compared to glass, the two types of material can be obtained from the same raw materials. The difference lies, however, in the fact that, in the case of glass, the raw material is brought to its melting point and, once the liquid state is obtained, the raw material is shaped, for example by blowing or moulding. Conversely, to produce a part made of ceramic material, the first phase is to shape the raw material in powder form, at ambient temperature. Very often, this shaping step is realized by mixing the powder with a liquid or by using all kinds of additives to enhance the homogeneity of the blank of the desired final part, but also to influence the characteristics of said part. Next, the blank is fired at a temperature well below the melting point of the ceramic material. During this firing step, the ceramic powder particles aggregate with each other, which causes the elimination of most of the pores or cavities, and consequently the blank contracts and hardens, while maintaining its initial shape. This firing step is called sintering.

Ceramic materials generally have a crystalline structure, sometimes associated with an amorphous phase. Ceramic materials can be classified according to their application:

1. conventional ceramics, which are intended for food or ornamental use (pottery, tableware, earthenware, porcelain), or for construction (tiles, bricks, roof tiles);

2. so-called industrial or technical ceramics, of which the following can be mentioned:
electronic or functional ceramics used in applications utilising low currents (dielectric (insulating) ceramics, piezoelectric ceramics, conductive ceramics, magnetic ceramics, ceramic superconductors);
electrotechnical ceramics intended for applications utilising high electric power;
refractory ceramics for thermal applications;
ceramics for mechanical applications, such as structural ceramics and ceramics intended for machining operations (abrasive ceramics for polishing operations and carbide inserts for cutting tools);
ceramics used for making catalyst supports in the chemical industry and catalytic converters particularly in the automobile industry;
ceramics for optical applications (transparency, light emission):
ceramics intended to be used for nuclear fuel containment.

The present invention more particularly concerns technical ceramics.

Ceramic products can also be classified according to their chemical composition. The category of monolithic ceramic materials includes:

1. oxides, namely
siliceous products made from silica SiO₂;
aluminous products containing from 30 to 100% of alumina Al₂O₃
basic products made from magnesia MgO;
special products such as zirconia ZrO₂ or yttrium stabilized tetragonal zirconia polycrystals (Y-TZP).

2. non-oxides, namely carbides, nitrides and borides.

There also exist composite ceramic materials, such as ceramic matrix materials reinforced with a ceramic, for example with zirconia ZrO₂, or ceramic matrix materials reinforced with a metal.

The present invention concerns both oxides and non-oxides.

Ion implantation processes consist of the surface bombardment of the treated object, for example by means of a source of singly or multiply charged ions of the electron cyclotron resonance type. This type of device is also known as an ECR ion source.

An ECR ion source makes use of electron cyclotron resonance to create a plasma. A volume of low pressure gas is ionised by means of microwaves injected at a frequency corresponding to the electronic cyclotron resonance defined by a magnetic field applied to an area located inside the volume of gas to be ionised. The microwaves heat the free electrons present in the volume of gas to be ionised. Under the effect of thermal agitation, these free electrons will collide with the atoms or molecules of gas and cause them to ionise. The ions produced correspond to the type of gas used. This gas may be pure or compound. It may also be a vapour obtained from a solid or liquid material. The ECR ion source is capable of producing singly charged ions, i.e. ions whose degree of ionisation is equal to 1, or multiply charged ions, i.e. ions whose degree of ionisation is higher than 1.

An ECR type ion source is schematically illustrated in FIG. 1 annexed to the present Patent Application. Designated as a whole by the general reference numeral 1, an ECR ion source includes an injection stage 2 into which a volume 4 of gas to be ionised is introduced and a hyperfrequency wave 6, a magnetic confinement stage 8 in which a plasma 10 is created, and an extraction stage 12, which allows the ions to be extracted and accelerated from plasma 10 by means of an anode 12a and a cathode 12b between which a high voltage is applied. An ion beam 14 produced at the output of ECR ion source 1 strikes a surface 16 of a part to be treated 18 and penetrates more or less deeply the volume of part to be treated 18.

Ion implantation by bombarding the surface of a treated object has many effects including modifying the microstructure of the materiel from which the treated object is made, improving corrosion resistance, improving tribological properties and, more generally, improving mechanical properties. Several studies have thus evidenced the increase in hardness of copper and bronze by nitrogen ion implantation. It has also been demonstrated that nitrogen or neon implantation in copper increases its fatigue resistance. Likewise, studies have shown that nitrogen implantation, even at a low dose (1.10¹⁵ and 2.10¹⁵ ions·cm⁻²) is sufficient to significantly modify the shear modulus of copper.

It is thus understood that ion implantation by bombarding the surface of a treated object offers great advantages from a scientific as well as a technical and industrial viewpoint.

Nevertheless, studies carried out to date have only concerned the treatment of solid objects. Yet, these solid objects are necessarily limited by the shapes and geometry that they can be given by means of conventional machining techniques (drilling, milling, boring, etc.).

There therefore existed a need in the state of the art for objects whose mechanical properties could be significantly improved while imposing almost no limit on the shape that such objects could take.

### SUMMARY OF THE INVENTION

It is an object of the present invention to meet the aforementioned need, in addition to others, by proposing a method for surface treatment of a ceramic material making it possible to realize objects whose geometric shapes are practically free of any constraint, while offering modified and improved physical and chemical properties.

To this end, the present invention therefore concerns a method for surface treatment of a ceramic material, this method comprising the step consisting in providing a powder formed of a plurality of particles of a ceramic material, and in directing towards a surface of these particles a beam of singly or multiply charged ions produced by a source of singly or multiply charged ions, the particles having a generally spherical shape.

According to preferred embodiments of the invention:
the source of singly or multiply charged ions is of the electronic cyclotron resonance (ECR) type;
the ceramic powder particles are agitated throughout the duration of the ion implantation process;
the grain size of the ceramic powder particles used is such that substantially 50% of all said particles have a dimension smaller than 2 micrometres, the dimension of the ceramic power particles used not exceeding 60 micrometres;
the material to be ionised is chosen from among carbon, nitrogen and boron;
the singly or multiply charged ions are accelerated at a voltage comprised between 15,000 and 35,000 volts;
the implanted ion dose is comprised between 1.10¹⁴ and 5.10¹⁷ ions·cm⁻², preferably between 1.10¹⁶ and 1.10¹⁷ ions·cm⁻²
the maximum ion implantation depth is from 150 to 250 nm;
the ceramic material treated according to the ion implantation process of the present invention is a carbide, in particular a titanium carbide TiC or a silicon carbide SiC;
the ceramic material of the carbide type is bombarded with nitrogen ions N to form a carbonitride, particularly titanium carbonitride TiCN or silicon carbonitride SiCN;
the ceramic material treated according to the ion implantation process of the invention is a nitride, in particular a silicon nitride Si₃N₄;
the ceramic material of the nitride type is bombarded with an ion dose comprised between 1*10¹⁶ cm⁻² and 1*10¹⁷ cm⁻².
the ceramic material treated according to the ion implantation process of the invention is an oxide, particularly zirconia ZrO₂ or alumina Al₂O₃;
the ceramic material of the oxide type is bombarded with nitrogen ions to form an oxynitride, particularly zirconium oxynitrate hydrate ZrO(NO₃)₂, or zirconium nitride ZrN if the ion bombardment is continued for a sufficiently long time, or aluminium oxynitride AlOₓN_{y};
the oxide ceramic material is bombarded with carbon ions to form a carbonitride, particularly zirconia carbide ZrO₂C, or zirconium carbide ZrC;
the oxide ceramic material is bombarded with boron ions to form an oxyboride, particularly zirconia boride ZrO₂B, or zirconium diboride ZrB₂ if the ion bombardment is continued for a sufficiently long time,

The present invention also concerns a ceramic powder particle with a ceramic surface and a ceramic core, and more particularly with a surface that is a carbide, a nitride or a boride of the ceramic material from which the ceramic powder particles are made.

As a result of these features, the present invention provides a method for treating a ceramic material in powder form, wherein the particles forming this powder maintain their initial ceramic structure at their core, whereas, at the surface and to a certain depth, the singly or multiply charged ions with which the ceramic powder particles are bombarded modify the surface properties of the ceramic powder particles, improving, in particular, the compactability and sinterability of said ceramic powder particles, which, at a later stage, improves the machining properties and the tribological properties of parts made with these ceramic powder particles.

It will be noted that, after ion implantation treatment, the ceramic powder particles are ready to be used in ceramic powder sintering processes, such as sintering at atmospheric pressure or hot isostatic pressing known as HIP. Further, because the surface of the ceramic powder particles is transformed into a boride, carbide or nitride of the ceramic material that forms the particles, the initial physical and mechanical properties of these powders, such as rheology, fluidity or wettability, are modified. Consequently, the properties of surface coatings and of solid parts made with such powders, such as hardness, tribology or aesthetic appearance, are improved.

Preferably, the particles forming the ceramic powder are agitated throughout the duration of the ion implantation treatment, so that these particles are exposed to the ions of the implantation beam homogeneously over their entire surface.

### BRIEF DESCRIPTION OF THE DRAWINGS

Other features and advantages of the present invention will appear more clearly from the following detailed description of an example implementation of the method according to the invention, this example being given purely by way of non-limiting illustration with reference to the annexed drawing, in which:

FIG. 1, cited above, is a schematic representation of an ECR ion source;

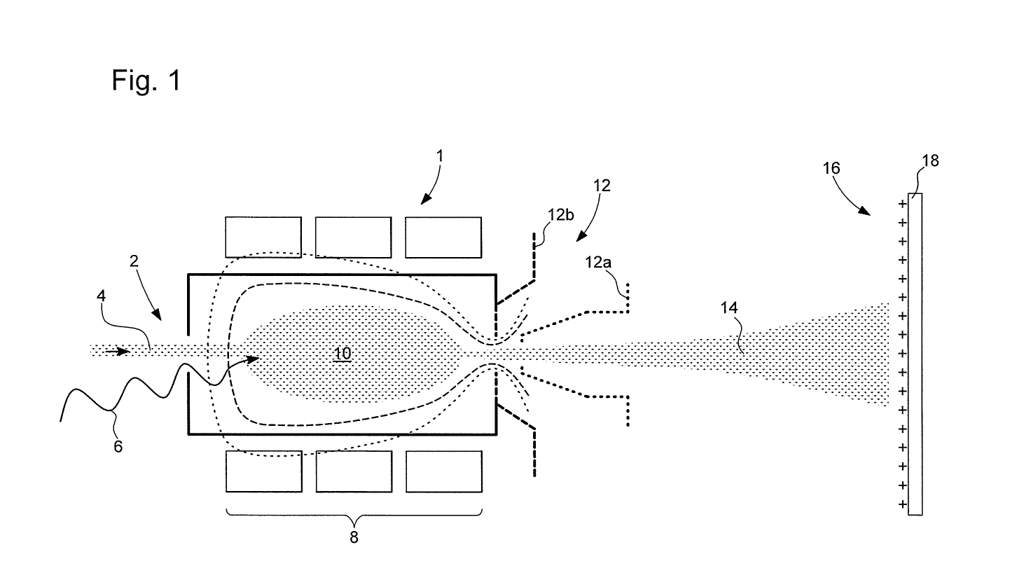

FIG. 2 is a cross-sectional view of an alumina particle Al₂O₃ whose radius is around 1 micrometre, and which has been bombarded with a nitrogen ion beam N⁺, and

FIG. 3 is a schematic representation of an ECR ion source used within the scope of the present invention.

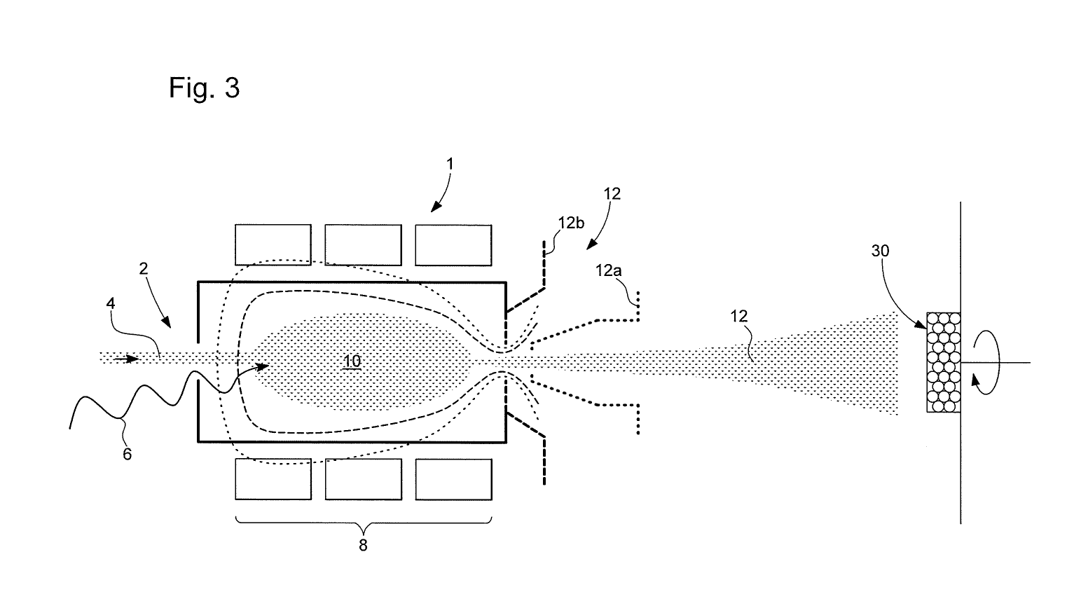

### DETAILED DESCRIPTION OF ONE EMBODIMENT OF THE INVENTION

The present invention proceeds from the general inventive idea which consists subjecting ceramic powder particles to a process of ion implantation treatment in the surface of said particles. When bombarding the particles of a ceramic powder with highly accelerated, singly or multiply charged ions at electrical voltages on the order of 15,000 to 35,000 volts, it becomes clear that these ions combine with the atoms of the ceramic material to form a new type of ceramic. To a certain depth from the surface of the ceramic powder particles, the latter are transformed, for example, into a carbide or nitride of the ceramic material from which the particles are made. Advantageously, the mechanical and physical properties, especially the hardness, tribological properties and machinability of these ceramic powder particles are substantially improved. The improvement in the mechanical and physical properties of the ceramic powder particles provided with a boride, carbide or nitride ceramic surface layer is maintained when these ceramic powders are used to make solid parts by powder sintering techniques, such as sintering at atmospheric pressure or HIP.

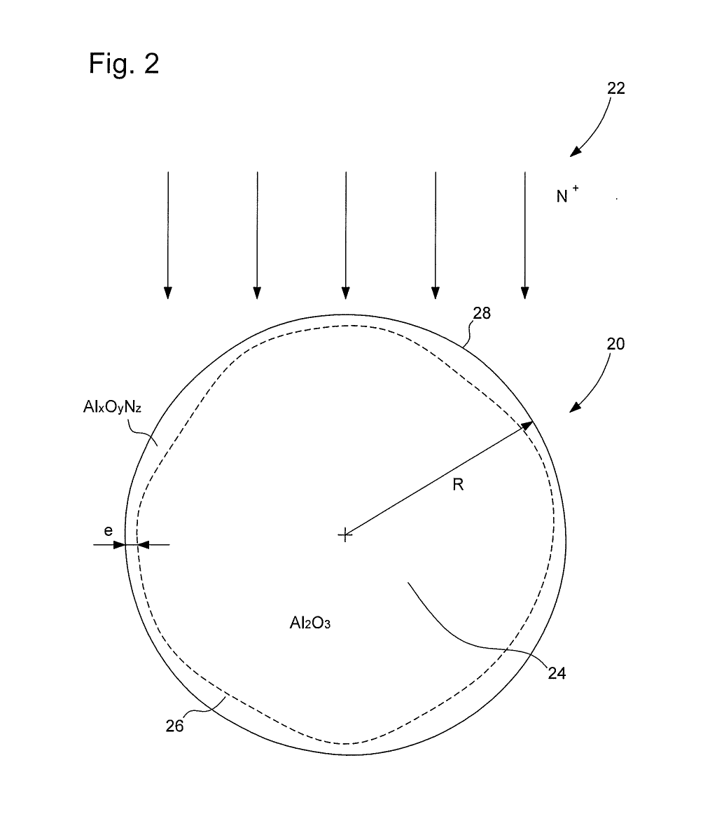

FIG. 2 is a cross-sectional view of an alumina particle Al₂O₃. For the sake of clarity, it will be assumed for the purposes of demonstration that this alumina particle Al₂O₃ is substantially spherical, it being understood that, in reality, such alumina particles Al₂O₃ actually have a polyhedral shape. Designated as a whole by the general reference number 20, this alumina particle Al₂O₃ has a radius R of around 1 micrometre. This alumina particle 20 was bombarded with a nitrogen ion beam N+ designated by the reference number 22. As shown in FIG. 2, alumina particle 20 has a core 24 of pure alumina and an external layer or shell 26 mainly formed of aluminum oxynitride AlₓO_{y}N_{z} whose stoichiometry varies as a function of depth from the surface of alumina particle 20.

The thickness e of this external layer 26 is on the order of 7% of radius R of alumina particle 20, i.e. around 70 nanometres. This external layer 26 is mostly formed of aluminum oxynitride AlₓO_{y}N_{z}, which is a ceramic material. According to the invention, the concentration of AlₓO_{y}N_{z} increases from external surface 28 of alumina particle 20 to around 15% of radius R of alumina particle 20, i.e. around 140 nanometres, and then decreases to a depth of around 200 nm under the surface of alumina particle 20 where it is substantially zero.

More specifically, the composition of two samples of alumina Al₂O₃, referred to as A and B respectively, was analysed by X-ray photoelectron spectroscopy (XPS). These two alumina samples A and B were bombarded with nitrogen ions N+, and the nitrogen concentration from the surface towards the core of these samples was then examined by XPS analysis.

With regard to the XPS analysis of alumina sample A, tests show that the nitrogen atoms that bombard and penetrate the original alumina particle Al₂O₃ bond, on the one hand, to the aluminium atoms that form part of the composition of aluminium oxynitride AlₓO_{y}N_{z}, and, on the other hand, do not bond to the aluminium atoms. More specifically, XPS analyses show that the atomic weight concentration of nitrogen bonded in the aluminium oxynitride particles AlₓO_{y}N_{z} has two levels from the surface towards the core of the alumina particles AlₓO_{y}N_{z}:
the first nitrogen concentration level appears at a depth of approximately 70 nm from the external surface of the particles. The average atomic percent concentration of nitrogen bonded to the aluminium of the aluminium oxynitride AlₓO_{y}N_{z} is on the order of 6.3%. Further, the average stoichiometry of the oxynitride layer at this level is close to AlO_{1.2}N_{0.16}.
the second nitrogen concentration level appears at a depth of around 140 nm. The average atomic percent concentration of nitrogen bonded to aluminium is on the order of 3.6%, i.e. almost half less than the concentration of nitrogen bonded to aluminium observed at a depth of 70 nm. The average stoichiometry of the aluminium oxynitride layer at this level is close to AlO_{1.3}N_{0.08}.
Finally, beyond a depth in excess of 140 nm, there is an exponential drop in the concentration of nitrogen bonded to the aluminium that forms part of the composition of aluminium oxynitride AlₓO_{y}N_{z}. At a considered depth of more than 200 nm from the surface of the alumina Al₂O₃ particles, there is a stoichiometric ratio between oxygen and aluminium that is very close to that of alumina Al₂O₃.

With regard to alumina sample B, XPS analysis shows that, in this case too, the nitrogen atoms that bombard and penetrate the original alumina particle Al₂O₃ bond, on the one hand, to the aluminium atoms that form part of the composition of aluminium oxynitride AlₓO_{y}N_{z}, and, on the other hand, do not bond to the aluminium atoms. More specifically, XPS analyses show that the atomic weight concentration of nitrogen bonded in the aluminium oxynitride particles AlₓO_{y}N_{z} has two levels from the surface towards the core of the alumina particles AlₓO_{y}N_{z}:
the first nitrogen concentration level appears at a depth of approximately 25 nm from the external surface of the particles. The average atomic percent concentration of nitrogen bonded to aluminium is on the order of 3.6%. Further, the average stoichiometry of the aluminium oxynitride layer at this level is close to AlO_{1.3}N_{0.09}.
the second nitrogen concentration level appears at a depth of around 120 nm. The average atomic percent concentration of nitrogen bonded to aluminium is on the order of 4.7%, i.e. slightly more than at a depth of 25 nm. The average stoichiometry of the aluminium oxynitride layer at this level is close to AlO_{1.3}N_{0.11}.
Finally, beyond a depth in excess of 120 nm, there is an exponential drop in the concentration of nitrogen bonded to the aluminium that forms part of the composition of aluminium oxynitride AlₓO_{y}N_{z}. At a considered depth of more than 200 nm from the surface of the alumina Al₂O₃ particles, there is a stoichiometric ratio between oxygen and aluminium that is very close to that of alumina Al₂O₃.

It is evident that the present invention is not limited to the preceding description and that various simple modifications and variants can be envisaged by those skilled in the art without departing from the scope of the invention as defined by the annexed claims. It will be understood, in particular, that given that the ceramic particles envisaged here have a general polyhedral shape, the ‘dimension’ of such particles means the largest external dimension of such a particle. It will be noted finally that, according to the invention, the ECR ion source is capable of producing singly or multiply charged ions, i.e. ions whose degree of ionisation is higher than or equal to 1, wherein the ion beam can include ions that all have the same degree of ionisation or can result from a mixture of ions having different degrees of ionisation.

### Nomenclature

1. ECR ion source

2. Injection stage

4. Volume of gas to be ionised

6. Hyperfrequency wave

8. Magnetic confinement stage

10. Plasma

12. Extraction stage

12a Anode

12b. Cathode

14. Ion beam

16. Surface

18. Part to be treated

20. Alumina particle Al₂O₃

R. Radius

22. Nitrogen ion beam N⁺

24. Core or centre

26. External layer or shell

e. Thickness

28. External surface

30. Ceramic powder particles

1. A method for surface treatment of a ceramic material in powder form, the method comprising:
providing a powder formed of a plurality of particles of the ceramic material to be treated; and
subjecting said ceramic powder particles to an ion implantation process by directing towards an external surface of said particles a beam of singly or multiply charged ions produced by a source of singly or multiply charged ions.

2. The method according to claim 1, wherein the ceramic powder particles are agitated throughout the entire duration of the ion implantation process.

3. The method according to claim 1, wherein the grain size of the particles of ceramic powder used is such that substantially 50% of all the particles have a dimension smaller than 2 micrometres.

4. The method according to claim 2, wherein the grain size of the particles of ceramic powder used is such that substantially 50% of all the particles have a dimension smaller than 2 micrometres.

5. The method according to claim 3, wherein the dimension of the ceramic powder particles used is comprised between 1.2 micrometres and 63 micrometres.

6. The method according to claim 4, wherein the dimension of the ceramic powder particles used is comprised between 1.2 micrometres and 63 micrometres.

7. The method according to claim 1, wherein the ceramic material is a carbide, a nitride, a boride or an oxide.

8. The method according to claim 7, wherein the carbide ceramic material is bombarded with nitrogen ions N to form a carbonitride.

9. The method according to claim 8, wherein the ceramic material is a titanium carbide TiC or a silicon carbide SiC, and wherein the product obtained after bombardment is titanium carbonitride TiCN, or silicon carbonitride SiCN respectively.

10. The method according to claim 7, wherein the nitride ceramic material is bombarded with an ion dose comprised between 1*10¹⁶ cm⁻² and 1*10¹⁷ cm⁻².

11. The method according to claim 10, wherein the ceramic material is a silicon nitride Si₃N₄.

12. The method according to claim 7, wherein the oxide ceramic material is bombarded with nitrogen ions to form an oxynitride.

13. The method according to claim 12, wherein the ceramic material is zirconia ZrO₂ or alumina Al₂O₃, and in that the product obtained after bombardment is zirconia nitride ZrₓO_{y}N_{z}, or zirconium nitride ZrN, or aluminium oxynitride AlₓO_{y}N_{z}.

14. The method according to claim 7, wherein the oxide ceramic material is bombarded with carbon ions to form an oxycarbide.

15. The method according to claim 14, wherein the ceramic material is zirconia ZrO₂ or alumina Al₂O₃, and in that the product obtained after bombardment is zirconia carbide ZrO₂C, or zirconium carbide ZrC respectively.

16. The method according to claim 7, wherein the oxide ceramic material is bombarded with boron ions to form an oxyboride.

17. The method according to claim 16, wherein, if the ion bombardment is continued for a sufficiently long time, zirconium diboride ZrB₂ is obtained.

18. The method according to claim 1, wherein the ion implantation process is of the electron cyclotron resonance ECR type.

19. The method according to claim 18, wherein the singly or multiply charged ions are accelerated at a voltage comprised between 15,000 and 35,000 volts.

20. The method according to claim 18, wherein the implanted ion dose is comprised between 1.10¹⁴ and 5.10¹⁷ ions·cm⁻².

21. The method according to claim 19, wherein the implanted ion dose is comprised between 1.10¹⁴ and 5.10¹⁷ ions·cm⁻².

22. The method according to claim 18, wherein the ions penetrate the particles forming the ceramic material powder to a depth corresponding to around 20% of the dimension of said particles.

23. The method according to claim 18, wherein the ions penetrate the particles forming the ceramic material powder to a depth corresponding to around 20% of the dimension of said particles.

24. A material in powder form formed of a plurality of particles having a ceramic external layer and a ceramic core, said particles having a generally polyhedral shape, the external layer corresponding to a boride, a carbide or a nitride of the ceramic material from which the core of the ceramic powder particles is made.

25. The material according to claim 24, wherein around 50% of the particles have a dimension smaller than 2 micrometres.

26. The material according to claim 25, wherein the dimension of the ceramic powder particles used is comprised between 1.2 micrometres and 63 micrometres.

27. The material according to claim 24, wherein the ceramic material from which the ceramic powder particles are made is a boride, a carbide, oxide or a nitride.

28. The material according to claim 25, wherein the ceramic material from which the ceramic powder particles are made is a boride, a carbide, oxide or a nitride.

29. The material according to claim 26, wherein the ceramic material from which the ceramic powder particles are made is a boride, a carbide, oxide or a nitride.
